(19) United States
(12) Patent Application Publication
(10) Pub. No.: US 2025/0261546 A1
(43) Pub. Date: Aug. 14, 2025

(54) DISPLAY PANEL AND DISPLAY DEVICE

(71) Applicants: Hefei Visionox Technology Co., Ltd., Hefei (CN); Yungu (Gu’an) Technology Co., Ltd., Langfang (CN)

(72) Inventors: Yanhua CHENG, Hefei (CN); Wentao YING, Hefei (CN); Xiaokang ZHOU, Langfang (CN); Yiming JIA, Hefei (CN)

(73) Assignees: Hefei Visionox Technology Co., Ltd., Hefei (CN); Yungu (Gu’an) Technology Co., Ltd., Langfang (CN)

(21) Appl. No.: 19/193,889

(22) Filed: Apr. 29, 2025

(30) Foreign Application Priority Data
Jun. 7, 2024 (CN) 202410740606.2

(51) Int. Cl. H10K 59/80; H10K 59/122

(52) U.S. Cl. CPC H10K 59/879; H10K 59/122

(57) ABSTRACT

An embodiment of the present application provides a display panel, including: a substrate; a first film layer arranged on one side of the substrate and defining at least one pixel opening in an enclosing manner, the pixel opening including a bottom portion and a side wall arranged on a peripheral side of the bottom portion; a first electrode layer located at the bottom portion of the pixel opening; a reflective layer located on a side of the first film layer away from the substrate and covering at least the side wall; a light-emitting functional layer arranged on a side of the first electrode layer away from the substrate; and a second electrode layer arranged on a side of the light-emitting functional layer away from the substrate.

### CROSS-REFERENCE TO RELATED APPLICATIONS

The present application claims priority to Chinese Patent Application No. 202410740606.2, filed on Jun. 7, 2024 and entitled “DISPLAY PANEL AND DISPLAY DEVICE”, the disclosure of which is incorporated herein by reference in its entirety.

### FIELD

The present application relates to the field of display, and in particular to a display panel and a display device.

### BACKGROUND

In a display device, an organic light emitting diode (OLED) device is a device that uses a multi-layer organic thin film structure to generate electroluminescence, and has the advantages of light weight, high brightness, low power consumption, fast response, large angle of view, etc. With the wide application of OLED devices, the requirements for display of the OLED devices are increasingly high. However, there are still some problems with the display of OLED devices.

### SUMMARY

In view of this, embodiments of the present application provide a display panel and a display device, in order to improve the light extraction efficiency.

In a first aspect, an embodiment of the present application provides a display panel, including: a substrate; a first film layer arranged on one side of the substrate and defining at least one pixel opening in an enclosing manner, the pixel opening including a bottom portion and a side wall arranged on a peripheral side of the bottom portion; a first electrode layer located at the bottom portion of the pixel opening; a reflective layer located on a side of the first film layer away from the substrate and covering at least the side wall; a light-emitting functional layer arranged on a side of the first electrode layer away from the substrate; and a second electrode layer arranged on a side of the light-emitting functional layer away from the substrate.

In a second aspect, an embodiment of the present application provides a display device, including: a display panel described above.

In the above embodiments, a reflective layer is provided on the side wall, so that when large-angle light emitted by the light-emitting functional layer directly irradiates the side wall or is reflected and then irradiates the side wall, the reflective layer located on the side wall can reflect the light irradiating the side wall to change the angle of the light so as to convert the large-angle light into small-angle light that can be emitted smoothly when irradiating an encapsulation layer, thereby improving the light extraction efficiency.

### BRIEF DESCRIPTION OF THE DRAWINGS

FIG. 1 is a structural schematic diagram of a display panel according to an embodiment of the present application.

FIG. 2 is a top view of a first film layer of the display panel shown in FIG. 1.

FIG. 3 is a structural schematic diagram of a display panel according to another embodiment of the present application.

FIG. 4 is a structural schematic diagram of a display panel according to yet another embodiment of the present application.

FIG. 5 is a structural schematic diagram of a display panel according to yet another embodiment of the present application.

FIG. 6 is a structural schematic diagram of a display panel according to yet another embodiment of the present application.

FIG. 7 is a structural schematic diagram of a display panel according to yet another embodiment of the present application.

FIGS. 8A and 8B are structural schematic diagrams of a display panel according to yet another embodiment of the present application, respectively.

FIG. 9 is a structural schematic diagram of a display panel according to yet another embodiment of the present application.

FIG. 10 is a structural schematic diagram of a display panel according to yet another embodiment of the present application.

FIG. 11 is a structural schematic diagram of a display panel according to yet another embodiment of the present application.

FIG. 12 is a structural schematic diagram of a display panel according to yet another embodiment of the present application.

FIG. 13 is a structural schematic diagram of a display panel according to yet another embodiment of the present application.

FIG. 14 is a structural schematic diagram of a display panel according to yet another embodiment of the present application.

FIG. 15 is a structural schematic diagram of a display panel according to yet another embodiment of the present application.

FIG. 16 is a structural schematic diagram of a display panel according to yet another embodiment of the present application.

FIG. 17 is a structural schematic diagram of a display panel according to yet another embodiment of the present application.

FIG. 18 is a structural schematic diagram of a display panel according to yet another embodiment of the present application.

FIG. 19 is a structural schematic diagram of a display panel according to yet another embodiment of the present application.

FIG. 20 is a flowchart of a method for preparing a display panel according to an embodiment of the present application.

FIG. 21 is a flowchart of a method for preparing a display panel according to yet another embodiment of the present application.

FIG. 22 is a structural schematic diagram of a display device according to yet another embodiment of the present application.

### DETAILED DESCRIPTION OF THE EMBODIMENTS

A display panel has a film layer arrangement including a light-emitting device layer, an encapsulation layer, a touch layer, a protective layer, a polarizer and a cover plate. The light-emitting device layer includes an anode, a light-emitting functional layer and a cathode which are sequentially stacked. The light-emitting functional layer includes a hole injection layer (HIL), a hole transport layer (HTL), an electron block layer (EBL), an emission layer (EML), a hole block layer (HBL), an electron transport layer (ETL) and an electron injection layer (EIL) which are sequentially stacked. The encapsulation layer includes a first inorganic layer, an organic layer and a second inorganic layer. The first inorganic layer and the second inorganic layer are formed by a chemical vapor deposition (CVD) process, and the organic layer is formed by an ink jet printing (IJP) process. The first inorganic layer is made of a high-refractive index material, the organic layer is made of a low-refractive index material, a refractive index of the organic layer is less than a refractive index of the first inorganic layer, and most of the light ray emitted by the light-emitting device layer is subjected to total reflection at an interface between the first inorganic layer and the organic layer and is thus confined in a waveguide mode, resulting in a low light extraction efficiency.

Embodiments of the present application provide a display panel and a method for preparing same, and a display device, which can extract most of the light emitted by the light-emitting device layer, thereby improving the light extraction efficiency.

FIG. 1 is a structural schematic diagram of a display panel according to an embodiment of the present application. As shown in FIG. 1, the display panel includes a substrate 70, a first film layer 110, a reflective layer 30, a first electrode layer 201, a light-emitting functional layer 202 and a second electrode layer 203.

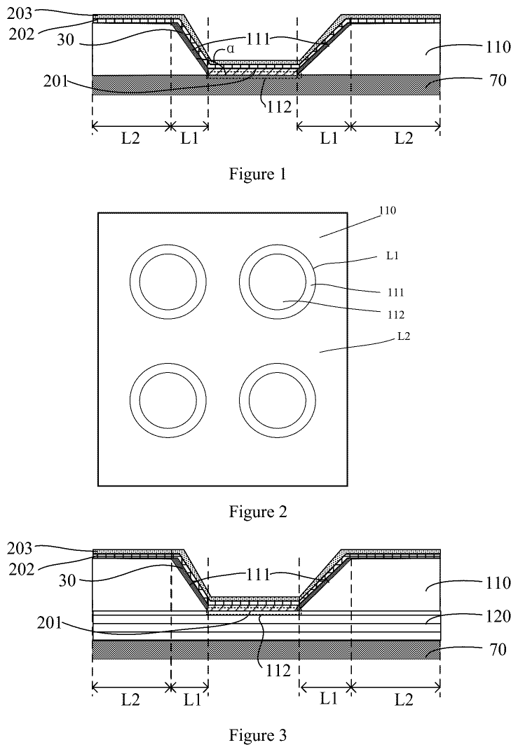

FIG. 2 is a top view of a first film layer of the display panel shown in FIG. 1. As shown in FIGS. 1 and 2, the first film layer 110 is arranged on one side of the substrate 70, the first film layer 110 defines at least one pixel opening in an enclosing manner, and a pixel opening includes a bottom portion 112 and a side wall 111 arranged on a peripheral side of the bottom portion 112. In one embodiment, the side wall 111 is a straight line or an arc in a cross section along a direction perpendicular to the substrate. For reasons of processes, with respect to the cross section along the direction perpendicular to the substrate, it is impossible to ensure the side wall 111 to be completely straight, and the side wall 111 is usually an arc (as shown in FIG. 8B). Regardless of whether the side wall is a straight line or an arc, an angle α between the bottom portion 112 and the side wall 111 is an obtuse angle. In this case, when light irradiates the side wall 111, an emergence angle of the light irradiating the side wall 111 can be changed.

In the case of the side wall being straight, the obtuse angle is greater than or equal to 135° and less than or equal to 145°. For example, the obtuse angle may be any one of 135°, 138°, 140°, 142° and 145°. Since the angle α between the bottom portion 112 and the side wall 111 is an obtuse angle, the emergence angle of the light irradiating the side wall 111 can be changed.

The first film layer 110 includes a first region L1 located between the side wall 111 and the substrate 70 and a second region L2 surrounding the pixel opening, an orthographic projection of the first region L1 on the substrate 70 overlapping with an orthographic projection of the side wall 111 on the substrate 70. In the embodiments of the present application, the first film layer 110 is a pixel defining layer. A maximum thickness of the first film layer 110 in the direction perpendicular to the substrate 70 is greater than or equal to 1 μm and less than or equal to 2 μm. For example, the maximum thickness of the first film layer 110 may be any one of 1 μm, 1.3 μm, 1.5 μm, 1.8 μm and 2 μm.

In one embodiment, as shown in FIG. 3, the display panel further includes a sixth film layer 120 arranged on a side of the first film layer 110 close to the substrate 70. The sixth film layer 120 is a planarization layer. The sum of the maximum thickness of the first film layer 110 and a maximum thickness of the sixth film layer 120 in the direction perpendicular to the substrate 70 is greater than or equal to 4 μm and less than or equal to 5 μm. For example, the sum of the maximum thickness of the first film layer 110 and the maximum thickness of the sixth film layer 120 may be any one of 4 μm, 4.2 μm, 4.5 μm, 4.8 μm and 5 μm. The first film layer 110 and the sixth film layer 120 in the figures are only for illustration and are not drawn to scale.

The first film layer 110 and/or the sixth film layer 120 are/is made of an organic material. In one embodiment, the first film layer 110 and the sixth film layer 120 are made of the same material. In one embodiment, the first film layer 110 and the sixth film layer 120 are prepared synchronously. Specifically, a pixel opening is directly formed in the organic material layer, the organic material layer located at the bottom portion of the pixel opening is the sixth film layer 120 (i.e., the planarization layer), and the organic material layer surrounding the peripheral side of the pixel opening is the first film layer 110 (i.e., the pixel defining layer). In the embodiments of the present application, the pixel defining layer and the planarization layer are formed in one procedure, which simplifies the preparation process and reduces the number of masks required. In one embodiment, the pixel opening may be formed by laser etching, photoetching, chemical dry etching, halftone process, etc., which are not limited in the present application. For example, the organic material layer may be exposed for hole formation by means of a halftone process to form the pixel opening. The pixel opening is formed by forming a hole in the organic material layer, the sixth film layer 120 located at the bottom portion of the pixel opening is equivalent to a planarization layer, and the first film layer 110 surrounding the peripheral side of the pixel opening is equivalent to a pixel defining layer. The circular pixel opening in the embodiments of the present application is only exemplary. The shape of the pixel opening may be adjusted according to actual requirements. For example, the pixel opening may be square, elliptical, triangular, etc.

Still referring to FIGS. 1 and 3, the first electrode layer 201 is located at the bottom portion 112 of the pixel opening. The first electrode layer 201 is electrically connected to a pixel circuit in an array film layer (not shown). In one embodiment, the first electrode layer 201 includes a reflective electrode material to reflect the light irradiating the bottom portion 112, which ensures emission of light from above the pixel opening (i.e., top emission), thereby improving the light extraction efficiency. In one embodiment, the first electrode layer 201 may be a metal layer, and for example, the first electrode layer 201 may be prepared from silver, gold, platinum, etc.; or the first electrode layer 201 may be of a stacked structure that includes a metal and a conductive oxide. For example, the metal may be silver (Ag), and the conductive oxide may be indium tin oxide (ITO). In the embodiments of the present application, the stacked structure includes indium tin oxide/silver/indium tin oxide (ITO/Ag/ITO).

The reflective layer 30 is located on a side of the first film layer 110 away from the substrate 70, and the reflective layer 30 covers at least the side wall 111. The reflective layer 30 may be a metal layer. For example, the reflective layer 30 may be prepared from silver, gold, platinum, etc. In one embodiment, the reflective layer 30 may be of a stacked structure that includes metal and conductive oxide. In one embodiment, the stacked structure includes indium tin oxide/silver/indium tin oxide.

The light-emitting functional layer 202 is arranged on a side of the first electrode layer 201 away from the substrate 70. The light-emitting functional layer 202 may include a hole injection layer, a hole transport layer, an electron block layer, an emission layer, a hole block layer, an electron transport layer and an electron injection layer, which are sequentially stacked. In the embodiments of the present application, the light-emitting functional layer 202 may be prepared by an evaporation process. In one embodiment, the light-emitting functional layer 202 covers the first electrode layer 201 and the first region L1 and the second region L2 of the first film layer 10, that is, the light-emitting functional layer 202 may be prepared integrally, thereby simplifying the preparation process.

The second electrode layer 203 is arranged on a side of the light-emitting functional layer 202 away from the substrate 70. In the embodiments of the present application, the first electrode layer 201 is an anode, and the second electrode layer 203 is a cathode; or the first electrode layer 201 is a cathode, and the second electrode layer 203 is an anode. In one embodiment, the second electrode layer 203 covers the first electrode layer 201 and the first region L1 and the second region L2 of the first film layer 10, that is, the second electrode layer 203 may be prepared integrally, thereby simplifying the preparation process.

In the embodiments of the present application, the reflective layer 30 is arranged on the side wall 111, and the angle α between the side wall 111 and the bottom portion 112 is the obtuse angle, so that when large-angle light emitted by the light-emitting functional layer 202 directly irradiates the side wall 111 or is reflected and then irradiates the side wall, the reflective layer 30 located on the side wall can reflect the light irradiating the side wall 111 to change the angle of light to convert the large-angle light into small-angle light that can be emitted smoothly when irradiating an encapsulation layer, thereby improving the light extraction efficiency. In addition, the first electrode layer 201 includes a reflective electrode material to reflect the light irradiating the bottom portion 112, which ensures emission of light from above the pixel opening (i.e., top emission), thereby further improving the light extraction efficiency.

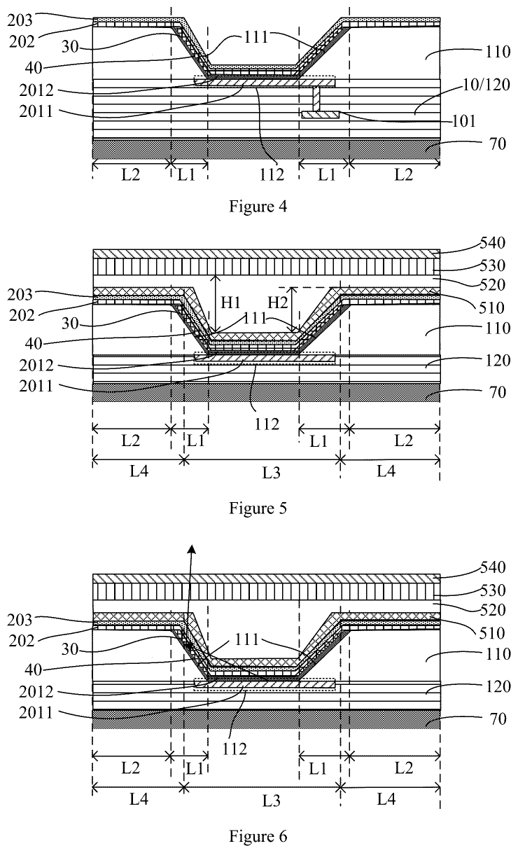

FIG. 4 is a structural schematic diagram of a display panel according to yet another embodiment of the present application. The difference between the display panel shown in FIG. 4 and the display panel shown in FIG. 3 lies in that the first electrode layer 201 includes a first sub-electrode layer 2011 and a second sub-electrode layer 2012 located on a side of the first sub-electrode layer 2011 away from the substrate 70.

The first sub-electrode layer 2011 includes a reflective material, or the second sub-electrode layer 2012 includes a reflective material. The first sub-electrode layer 2011 may be a metal layer or a conductive oxide layer. The second sub-electrode layer 2012 may be a metal layer or of a stacked structure. In one embodiment, the first sub-electrode layer 2011 is made of a material including indium tin oxide; and the second sub-electrode layer 2012 is of a stacked structure that includes indium tin oxide/silver/indium tin oxide. A thickness of the first sub-electrode layer 2011 in the direction perpendicular to the substrate 70 is greater than or equal to 300 nm and less than or equal to 400 nm. For example, the thickness of the first sub-electrode layer 2011 may be any one of 300 nm, 330 nm, 350 nm, 370 nm and 400 nm. A thickness of the second sub-electrode layer 2012 in the direction perpendicular to the substrate 70 is greater than or equal to 120 nm and less than or equal to 130 nm. For example, the thickness of the second sub-electrode layer 2012 may be any one of 120 nm, 124 nm, 126 nm, 128 nm and 130 nm. In the embodiments of the present application, the light-emitting functional layer 202 may be prepared by an evaporation process. In one embodiment, the light-emitting functional layer 202 covers the second sub-electrode layer 2012 and the first region L1 and the second region L2 of the first film layer 10, that is, the light-emitting functional layer 202 may be prepared integrally, thereby simplifying the preparation process. In one embodiment, the second electrode layer 203 covers the second sub-electrode layer 2012 and the first region L1 and the second region L2 of the first film layer 10, that is, the second electrode layer 203 may be prepared integrally, thereby simplifying the preparation process.

Still referring to FIG. 4, the display panel includes an array film layer 10 located between the substrate 70 and the first film layer 110 and the pixel opening, the sixth film layer 120 shown in FIG. 3 (i.e., the planarization layer) is part of the array film layer 10, and specifically the sixth film layer 120 is the film layer in the array film layer 10 that is farthest from the substrate 70. In the embodiments of the present application, an orthographic projection of the first sub-electrode layer 2011 on the substrate 70 covers an orthographic projection of the bottom portion of the pixel opening on the substrate 70. The first sub-electrode layer 2011 is electrically connected to the pixel circuit in the array film layer 10. For example, the first sub-electrode layer 2011 is electrically connected to a metal layer 101 (e.g., an M3 metal layer) in the array film layer 10.

In the embodiments of the present application, during preparation of the first sub-electrode layer 2011, holes are formed in the array film layer 10 above the metal layer 121, a conductive layer is then prepared on a side of the sixth film layer 120 of the array film layer 10 away from the substrate 70 and can fill the holes, and then the conductive layer is patterned, so as to obtain the first sub-electrode layer 2011 in the embodiments of the present application. Providing the first sub-electrode layer 2011 can prevent the second sub-electrode layer 2012 from being directly electrically connected to the pixel circuit, so as to prevent formation of an uneven surface of the second sub-electrode layer 2012 caused by hole formation.

In one embodiment, the material of the second sub-electrode layer 2012 is the same as the material of the reflective layer 30, and in this case the second sub-electrode layer 2012 may be prepared synchronously with the reflective layer 30. The synchronous preparation of the second sub-electrode layer 2012 and the reflective layer 30 can simplify the preparation process and reduce the number of the masks used. However, since the second sub-electrode layer 2012 is connected to the pixel circuit by means of the first sub-electrode layer 2011, the light-emitting functional layer 202 located at the bottom portion of the pixel opening emits light, so that the reflective layer 30 prepared synchronously with the second sub-electrode layer 2012 is also electrically connected to the pixel circuit, that is, the reflective layer 30 is also conductive, which causes the light-emitting functional layer 202 located on the side wall 111 to emit light to result in crosstalk of light. In order to reduce or avoid the crosstalk of light, the display panel in the embodiments of the present application further includes an insulation layer 40.

The insulation layer 40 is located between the reflective layer 30 and the light-emitting functional layer 202 and covers at least the reflective layer 30. The insulation layer 40 may cover the entire reflective layer 30, or the insulation layer 40 may cover the reflective layer 30 and the surface, away from the substrate 70, of the first film layer 110 that is not covered by the reflective layer 30. In order to ensure that the light-emitting functional layer 202 located at the bottom portion 112 emits light normally, the insulation layer 40 should not cover the second sub-electrode layer 2012. The insulation layer 40 is made of an inorganic insulation material. In one embodiment, the insulation layer 40 is made of a high-dielectric-constant inorganic insulation material. For example, the inorganic insulation material includes at least one of silicon dioxide, silicon nitride and silicon oxynitride. A thickness of the insulation layer 40 in the direction perpendicular to the substrate 70 is greater than or equal to 150 nm and less than or equal to 200 nm. For example, the thickness of the insulation layer 40 may be any one of 150 nm, 160 nm, 175 nm and 200 nm. On the one hand, using a high-dielectric-constant inorganic insulation material can better ensure the electric insulation capability of the insulation layer 40 to prevent the light-emitting functional layer 202 located on the side wall 111 from emitting light, thereby reducing the crosstalk of light. On the other hand, the insulation layer 40 and the light-emitting functional layer 202 form microcavities. On the basis of the principle of ultra-thin film thickness interference between the microcavities, the length of the microcavities is controlled by controlling the thickness of the insulation layer 40 to achieve constructive interference so as to adjust the reflectivity of the light at the side wall 102, so that more light is reflected and then emitted from above the pixel opening, thereby further improving the light extraction efficiency. When the reflective layer 30 is not conductive, the insulation layer 40 may be omitted.

FIG. 5 is a structural schematic diagram of a display panel according to yet another exemplary embodiment of the present application. The difference between the display panel shown in FIG. 5 and the display panel shown in FIG. 4 lies in that the display panel shown in FIG. 5 further includes a second film layer 510, a third film layer 520, a fourth film layer 530 and a fifth film layer 540, which are sequentially stacked on a side of the second electrode layer 203 away from the substrate 70.

In one embodiment, a refractive index of the third film layer 520 is greater than or equal to a refractive index of the second film layer 510, such that the light emitted by the light-emitting functional layer 202 will not be totally reflected at an interface between the second film layer 510 and the third film layer 520, and the light can enter the third film layer 520 from the second film layer 510. The third film layer 520 fills at least the entire pixel opening, such that more light can irradiate the side wall 111 after total reflection. In addition, filling the entire pixel openings with the third film layer 520 can simplify the preparation process of the third film layer 520.

In one embodiment, a refractive index of the fourth film layer 530 is less than the refractive index of the third film layer 520. The third film layer 520 fills at least the entire pixel opening, and in this case the large-angle light emitted by the light-emitting functional layer 202 is totally reflected at the interface between the third film layer 520 and the fourth film layer 530, and the totally reflected light can irradiate the side wall 111. The side wall 111 is provided with the reflective layer 30 and the insulation layer 40, and the angle α between the bottom portion 112 and the side wall 111 is an obtuse angle, so that the reflective layer 30 and the insulation layer 40 can reflect the light irradiating the side wall 111 to change the angle of light to convert the large-angle light into small-angle light that can be emitted smoothly when irradiating the interface between the third film layer 520 and the fourth film layer 530 again, thereby improving the light extraction efficiency.

FIG. 6 is a structural schematic diagram of a display panel according to yet another embodiment of the present application. The display panel in FIG. 6 shows an optical path diagram of large-angle light. As shown in FIG. 6, the large-angle light emitted by the light-emitting functional layer 202 irradiates the side wall 111, and the light irradiating the side wall 111 is reflected by the reflective layer 30 and the insulation layer 40 on the side wall 111, sequentially passes through the second film layer 510, the third film layer 520, the fourth film layer 530 and the fifth film layer 540, and is then emitted. In the embodiments of the present application, the light is reflected once by the reflective layer 30 and the insulation layer 40, so that the large-angle light emitted by the light-emitting functional layer 202 is converted into small-angle light which, when irradiating the interface between the third film layer 520 and the fourth film layer 530, sequentially passes through the third film layer 520, the fourth film layer 530 and the fifth film layer 540 and is then emitted, instead of being totally reflected, thereby improving the light extraction efficiency.

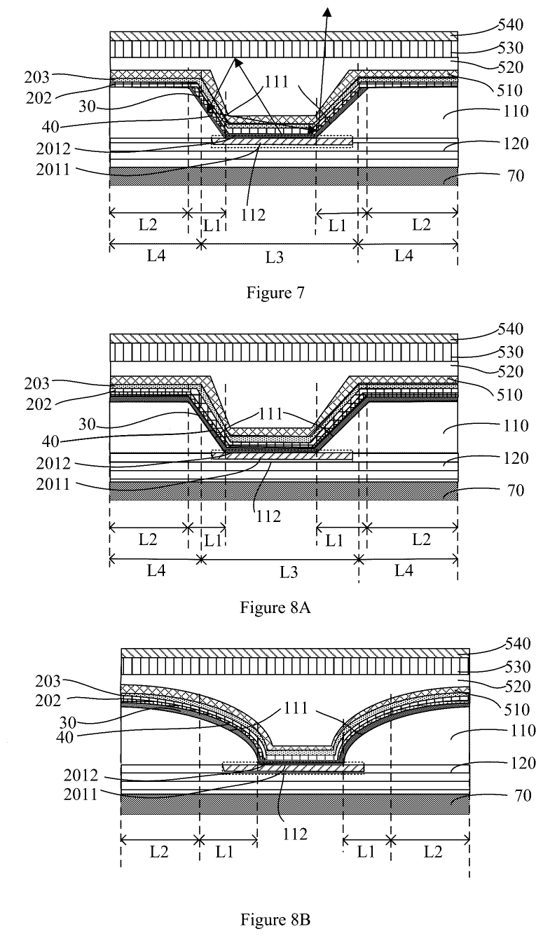

FIG. 7 is a structural schematic diagram of a display panel according to yet another embodiment of the present application. The display panel in FIG. 7 shows an optical path diagram of large-angle light. As shown in FIG. 7, the large-angle light emitted by the light-emitting functional layer 202 is totally reflected at the interface between the third film layer 520 and the fourth film layer 530, the totally reflected light irradiates the side wall 111, the light irradiating the side wall 111 is reflected by the reflective layer 30 and the insulation layer 40 on the side wall 111, the reflected light irradiates the other side wall 111 again, and the light irradiating the side wall 111 is reflected again by the reflective layer 30 and the insulation layer 40 on the side wall 111, then sequentially passes through the second film layer 510, the third film layer 520, the fourth film layer 530 and the fifth film layer 540, and is then emitted. In the embodiments of the present application, the light is reflected twice by the reflective layer 30 and the insulation layer 40, so that the large-angle light emitted by the light-emitting functional layer 202 is converted into small-angle light which, when irradiating the interface between the third film layer 520 and the fourth film layer 530 again, sequentially passes through the third film layer 520, the fourth film layer 530 and the fifth film layer 540 and is then emitted, instead of being totally reflected, thereby improving the light extraction efficiency.

The light emitted by the light-emitting functional layer 202 may be reflected once or multiple times on the reflective layer 30, so that the large-angle light is finally converted into small-angle light which, when irradiating the interface between the third film layer 520 and the fourth film layer 530 again, sequentially passes through the third film layer 520, the fourth film layer 530 and the fifth film layer 540 and is then emitted, instead of being totally reflected, thereby improving the light extraction efficiency.

In one embodiment, the second film layer 510 and the fifth film layer 540 are made of inorganic materials. In one embodiment, the third film layer 520 and the fourth film layer 530 are made of organic materials. In the embodiment of the present application, the specific materials of the second film layer 510, the third film layer 520, the fourth film layer 530 and the fifth film layer 540 are not limited, as long as the refractive index of the third film layer 520 is greater than or equal to the refractive index of the second film layer 510, and the refractive index of the fourth film layer 530 is less than the refractive index of the third film layer 520.

In the present application, the second film layer 510, the third film layer 520, the fourth film layer 530 and the fifth film layer 540 may be prepared by means of a conventional process, which is not limited in the present application. For example, the second film layer 510 and the fifth film layer 540 may be prepared by means of a chemical vapor deposition (CVD) process. For example, the third film layer 520 and the fourth film layer 530 may be prepared by means of an ink jet printing (IJP) process.

With the above embodiments, the second film layer 510 and the third film layer 520 are sequentially arranged on the side of the electrode layer 203 away from the substrate 70, the refractive index of the third film layer 520 being greater than or equal to the refractive index of the second film layer 510, so that the light emitted by the light-emitting functional layer 202 will not be totally reflected at the interface between the second film layer 510 and the third film layer 520, and the light emitted by the light-emitting functional layer 202 can enter the third film layer 520. The fourth film layer 530 is arranged on a side of the third film layer 40 away from the substrate 70, the refractive index of the fourth film layer 530 being less than the refractive index of the third film layer 520, and the reflective layer 30 and the insulation layer 40 are also arranged on the side wall 111, so that the large-angle light is totally reflected when irradiating the interface between the third film layer 520 and the fourth film layer 530, the totally reflected light can irradiate the side wall 111, the light irradiating the side wall 111 can be reflected by the reflective layer 30 and the insulation layer 40 located on the side wall 111 to change the angle of light, so that the light irradiating the side wall 111 due to total reflection is converted into small-angle light which, when irradiating the interface between the third film layer 520 and the fourth film layer 530 again, sequentially passes through the third film layer 520, the fourth film layer 530 and the fifth film layer 540 and is then emitted, instead of being totally reflected. In this way, the large-angle light emitted by the light-emitting functional layer 202 can also be extracted, thereby reducing the light loss and improving the light extraction efficiency. In addition, the second film layer 510, the third film layer 520, the fourth film layer 530 and the fifth film layer 540 are sequentially arranged on the side of the electrode layer 203 away from the substrate 70, and the distances of the second film layer 510, the third film layer 520, the fourth film layer 530 and the fifth film layer 540 from the light-emitting functional layer 202 are not large, which does not cause the problem of serious reduction in brightness at a large angle of view, and the process for preparing the second film layer 510, the third film layer 520, the fourth film layer 530 and the fifth film layer 540 is simple. In addition, the large-viewing-angle light is extracted by means of a combination of the reflective layer 30 (and the insulation layer 40), the third film layer 520 and the fourth film layer 530, so that there is no requirement for the large-viewing-angle light, and the success rate is high, thereby significantly improving the light extraction efficiency. Furthermore, in the embodiments of the present application, with the reasonable structural design, the light-emitting path of large-angle light is improved, so that as much light as possible can be extracted. The design concept is ingenious, and the effect is remarkable. In the embodiments of the present application, the third film layer 520 fills at least the pixel opening such that the interface where total reflection occurs shifts upward, the totally reflected light can irradiate the side wall 111 of the pixel opening, and the path of light is changed by the reflective layer 30 and the insulation layer 40 on the side wall, so as to maximize the coupling output of light trapped in the waveguide mode, which can achieve the advantages such as improving the light extraction efficiency without causing brightness attenuation at a large angle of view.

FIGS. 8A and 8B are structural schematic diagrams of a display panel according to yet another embodiment of the present application. The difference between the display panels shown in FIGS. 8A and 8B lies in that, in the display panel in FIG. 8B, the side wall 111 is an arc with respect to the cross section along the direction perpendicular to the substrate 70. with respect to the cross section along the direction perpendicular to the substrate 70, regardless of whether the side wall 111 is a straight line or an arc, the light irradiating the side wall 111 can be reflected. The difference between the display panels shown in FIGS. 8A and 8B and the display panel shown in FIG. 5 lies in that the reflective layer 30 covers the side wall 111 and a surface, away from the substrate, of the second region L2 of the first film layer 10. When the reflective layer 30 and the second sub-electrode layer 2012 are made of the same material, the reflective layer 30 and the second sub-electrode layer 2012 can be prepared synchronously, and in this case, during preparation of the reflective layer 30 and the second sub-electrode layer 2012, the second sub-electrode layer 2012 and the reflective layer 30 are directly prepared on the pixel opening and on the surface of the second region L2 away from the substrate 70, respectively. In this way, the preparation process can be simplified, and the number of the masks required can be reduced. In one embodiment, the reflective layer 30 may only cover the side wall 111, or cover the side wall 111 and at least part of the surface of the second region L2 away from the substrate 70, which can ensure the transmittance of light in the second region L2 to ensure implementation of other functions of the display panel.

Still referring to FIGS. 8A and 8B, since the second sub-electrode layer 2012 is electrically connected to the pixel circuit in the array film layer 10 by means of the first sub-electrode layer 2012, that is, the second sub-electrode layer 2012 is conductive, the reflective layer 30 prepared synchronously with the second sub-electrode layer 2012 is also conductive, so that in order to prevent the light-emitting functional layer 202 from emitting light in a region other than the bottom portion of the pixel opening, the insulation layer 40 needs to cover at least the reflective layer 30. During preparation of the insulation layer 40, the insulation layer 40 is prepared on a side of the reflective layer 30 away from the substrate 70. The insulation layer 40 covers the reflective layer 30, which can better ensure the electric insulation capability of the insulation layer 40 to prevent the light-emitting functional layer 202 located on the side wall 111 from emitting light, thereby reducing the crosstalk of light. Also, the insulation layer 40 and the light-emitting functional layer 202 form microcavities to adjust the reflectivity of light at the side wall 102, so that more light is reflected and then emitted from above the pixel opening, thereby further improving the light extraction efficiency. In the embodiments of the present application, the insulation layer 40 should not cover the second sub-electrode layer 2012 to avoid affecting light emission of the light-emitting functional layer 202.

Still referring to FIG. 5, the second film layer 510 includes a first section L3 and a second section L4 connected to the first section L3. The first section L3 covers the side wall 111 and the bottom portion 112, and the second section L4 is located on the surface of the side of the second region L2 away from the substrate 70. Since the reflective layer 30, the light-emitting functional layer 202 and the electrode layer 203 are arranged between the second film layer 510 and the first film layer 110, an orthographic projection of the first section L3 on the substrate 70 is less than an orthographic projection of the first region L1 on the substrate 70.

In the embodiments of the present application, the third film layer 520 fills at least the entire pixel opening, such that more light can irradiate the side wall 111 after total reflection. In addition, filling the entire pixel openings with the third film layer 40 can simplify the preparation process of the third film layer 520.

In the direction perpendicular to the substrate 70, a maximum thickness of the third film layer 520 is greater than or equal to the maximum distance between the first section L3 and the second section L4. As shown in FIG. 5, in the direction perpendicular to the substrate 70, the maximum thickness of the third film layer 520 is H1, and the maximum distance between the first section L3 and the second section L4 is H2. The maximum distance between the first section L3 and the second section L4 may be the maximum distance between a surface of the first section L3 away from the substrate 70 and a surface of the second section L4 away from the substrate 70, or the maximum distance between a surface of the first section L3 close to the substrate 70 and a surface of the second section L4 close to the substrate 70. When the maximum thickness of the third film layer 520 is greater than or equal to the maximum distance between the first section L3 and the second section L4, and the third film layer 520 may fill the entire pixel opening, which can ensure that the light totally reflected at the interface between the third film layer 520 and the fourth film layer 530 can be reflected by the reflective layer 30 and the insulation layer 40 which cover the side wall 111, so as to change the angle of light, so that the light can be extracted, thereby improving the light extraction efficiency. In addition, filling the entire pixel openings with the third film layer 520 can simplify the preparation process of the third film layer 520. In addition, when the maximum thickness of the third film layer 520 is greater than the maximum distance between the first section L3 and the second section L4, the side of the third film layer 520 away from the substrate 70 protrudes out of the pixel opening, and with the design of the shape of the side of the third film layer 520 away from the substrate 70, the light transmission path can be changed, which is conducive to extraction or convergence of light. In one embodiment, the maximum thickness of the third film layer 520 in the direction perpendicular to the substrate 70 is greater than or equal to 2 μm and less than or equal to 3 μm. For example, the maximum thickness of the third film layer 520 may be any one of 2 μm, 2.2 μm, 2.5 μm, 2.7 μm and 3 μm. Controlling the maximum thickness of the third film layer 520 to be within a suitable thickness range can improve the light extraction efficiency without causing brightness attenuation at a large angle of view.

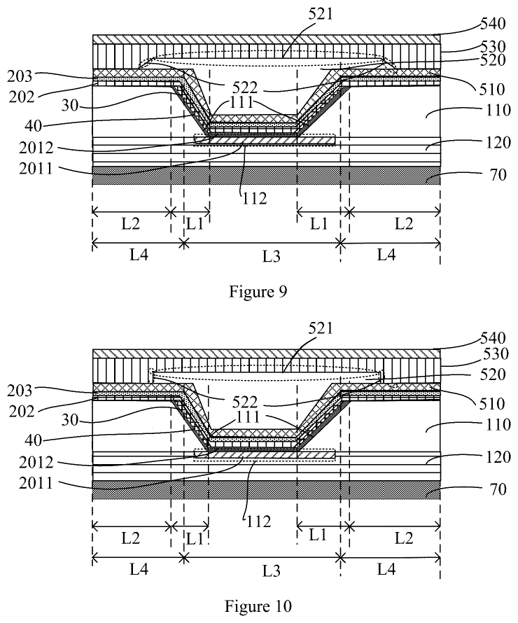

FIG. 9 is a structural schematic diagram of a display panel according to yet another embodiment of the present application. The difference between the display panel shown in FIG. 9 and the display panel shown in FIG. 5 lies in that at least part of the region of the second section L4 of the second film layer 510 overlaps with the fourth film layer 530. As shown in FIG. 9, the second film layer 510 includes a first section L3 and a second section L4 connected to the first section L3, the first section L3 covers the side wall 111 and the bottom portion 112, and the second section L4 is located on a surface of a side of the second region L2 away from the substrate 70.

In the embodiments of the present application, the entire region of the second section L4 of the second film layer 510 overlaps with the fourth film layer 50, or part of the region of the second section L4 of the second film layer 510 overlaps with the fourth film layer 50.

In the embodiments of the present application, by means of at least part of the region of the second section L4 of the second film layer 510 being overlapped with the fourth film layer 530, it is possible to prevent part of light from reaching the interface between the third film layer 520 and the second film layer 510 after total reflection at the interface between the third film layer 510 and the fourth film layer 530 and then being refracted at the interface between the third film layer 520 and the second film layer 510, so that the light cannot be emitted from a light-emitting side; or it is possible to prevent part of the light from being confined in a waveguide mode due to total reflection between the interface between the second film layer 510 and the third film layer 520 and the interface between the third film layer 520 and the fourth film layer 530.

In one embodiment, the side of the third film layer 520 away from the substrate 70 covers at least the pixel opening. With the design of the shape of the side of the third film layer 520 away from the substrate 70, the light transmission path can be changed, which is conducive to extraction or convergence of light.

Still referring to FIG. 9, the surface of the third film layer 520 away from the substrate includes a first portion 521 and a second portion 522. An orthographic projection of the first portion 521 on the substrate 70 covers at least the pixel opening, and the second portion 5222 surrounds the first portion 521 and is connected to the first portion 521. In one embodiment, the orthographic projection of the first portion 521 on the substrate 70 just covers the pixel opening, or the orthographic projection of the first portion 521 on the substrate 70 covers the pixel opening and at least part of the second region L2. In one embodiment, the shape of a cross section of the second portion 522 in the direction perpendicular to the substrate is any one of: an arc, a straight segment perpendicular to the substrate, and a straight segment at a preset angle to the substrate. The shape of the cross section of the first portion 521 in the direction perpendicular to the substrate is an arc or is a straight segment parallel to the substrate. In the embodiments of the present application, both the first portion 521 and the second portion 522 of the side of the third film layer 520 away from the substrate can converge the light emitted by the light-emitting functional layer 202, or one of the first portion 521 and the second portion 522 can converge the light emitted by the light-emitting functional layer 202. In the embodiments of the present application, setting or changing the shape of the first portion 521 and/or the second portion 522 achieves different degrees of convergence of the light emitted from the light-emitting functional layer 202.

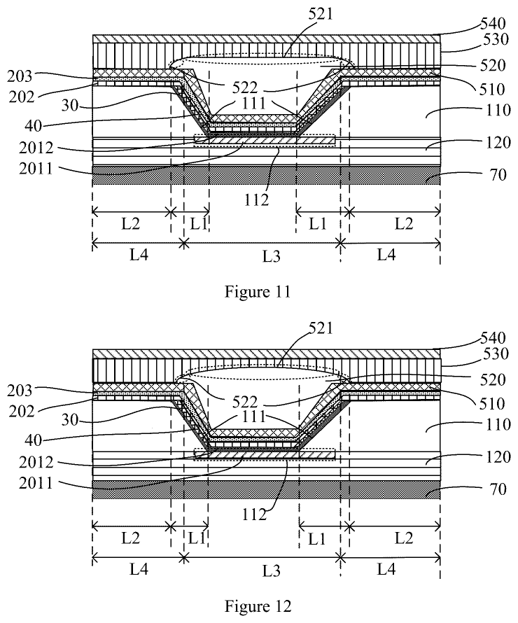

As shown in FIG. 9, the cross section of the first portion 521 in the direction perpendicular to the substrate 70 is a straight segment parallel to the substrate 70, and the cross section of the second portion 522 in the direction perpendicular to the substrate 70 is a straight segment forming a preset angle with the substrate 70. As shown in FIG. 10, the cross section of the first portion 521 in the direction perpendicular to the substrate 70 is a straight segment parallel to the substrate 70, and the cross section of the second portion 522 in the direction perpendicular to the substrate 70 is a straight segment perpendicular to the substrate 70. As shown in FIG. 11, the cross section of the first portion 521 in the direction perpendicular to the substrate 70 is a straight segment parallel to the substrate 70, and the cross section of the second portion 522 in the direction perpendicular to the substrate 70 is an arc. As shown in FIG. 12, the cross section of the first portion 521 in the direction perpendicular to the substrate 70 is an arc, and the cross section of the second portion 522 in the direction perpendicular to the substrate 70 is also an arc. In one embodiment, the first portion 521 and the second portion 522 are arc-shaped formed by the same circular arc. The shapes of the first portion 521 and the second portion 522 shown in the embodiments of the present application are only exemplary, and can be selected or adjusted in the art according to requirements.

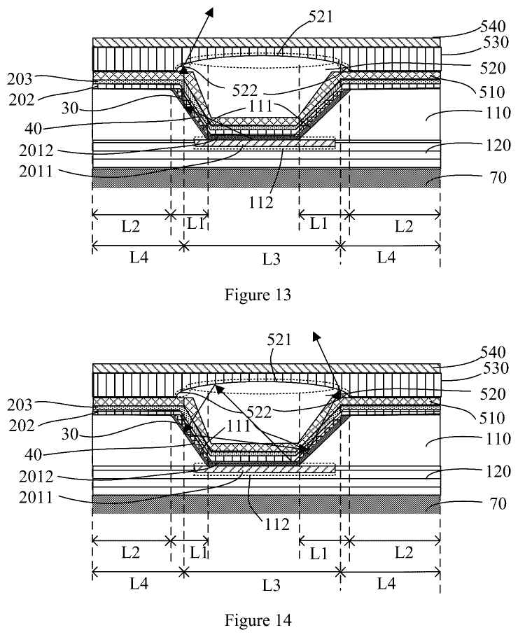

FIG. 13 is a structural schematic diagram of a display panel according to yet another embodiment of the present application. The display panel in FIG. 13 shows an optical path diagram of large-angle light. The difference between the display panel shown in FIG. 13 and the display panel shown in FIG. 6 lies in the shape of the side of the third film layer 520 away from the substrate 70. In FIG. 13, since the side of the third film layer 520 away from the substrate 70 is arc-shaped, the direction of light irradiating the side of the third film layer 520 away from the substrate 70 can be changed such that the light is converged above the pixel opening. FIG. 14 is a structural schematic diagram of a display panel according to yet another embodiment of the present application. The display panel in FIG. 14 shows an optical path diagram of large-angle light. The difference between the display panel shown in FIG. 14 and the display panel shown in FIG. 7 lies in the shape of the side of the third film layer 520 away from the substrate 70. In FIG. 14, since the side of the third film layer 520 away from the substrate 70 is arc-shaped, the direction of light irradiating the side of the third film layer 520 away from the substrate 70 can be changed such that the light is converged above the pixel opening. FIGS. 13 and 14 are only illustrated with the shape of the third film layer 520 shown in FIG. 12 as an example. In the case of the third film layer 520 being in other shapes, the optical path diagram of large-angle light follows the same rule, which will not be repeated herein.

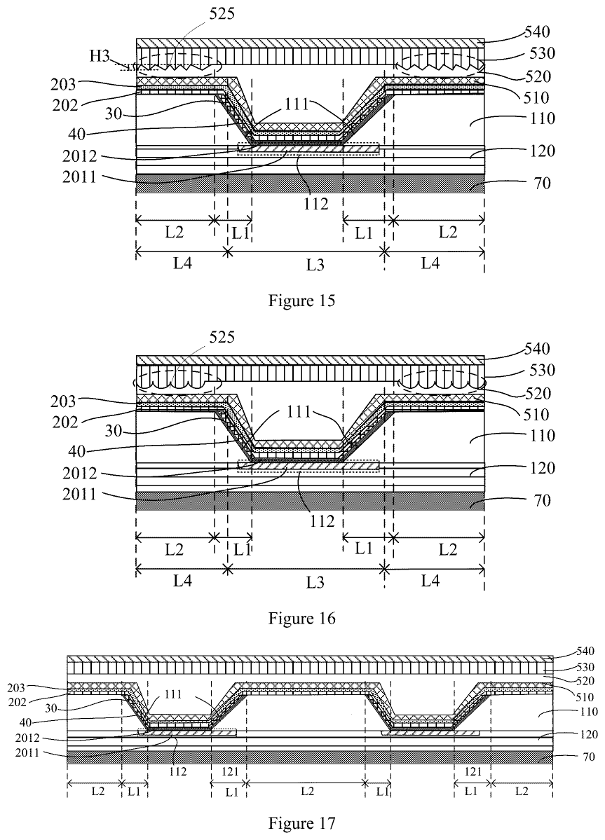

FIG. 15 is a structural schematic diagram of a display panel according to yet another embodiment of the present application. The difference between the display panel shown in FIG. 15 and the display panel shown in FIG. 5 lies in that the surface of the third film layer 520 away from the substrate 70 includes a patterned structure 525. The patterned structure 525 is located on the side of the second region L2 away from the substrate 70. The patterned structure 525 includes at least one protrusion.

In the direction perpendicular to the substrate 70, the cross section of the protrusion of the patterned structure 525 is a sawtooth protrusion (as shown in FIG. 15), an arc-shaped protrusion (as shown in FIG. 16), a trapezoidal protrusion, etc. The patterned structure 525 may include protrusions having the same cross-sectional shape or protrusions having different cross-sectional shapes. The depth H3 of the protrusions may be determined according to the specific circumstances. Regardless of the shape of the protrusions, it is only required that at least one protrusion is included such that the interface between the second film layer 510 and the fourth film layer 530 in the second region L2 is not a plane. Providing the patterned structure 525 can reduce the optical waveguide loss of lateral propagation. Specifically, providing the patterned structure 525 can change the light propagation path, thereby improving the light extraction efficiency.

FIG. 17 is a structural schematic diagram of a display panel according to yet another embodiment of the present application. The difference between the display panel shown in FIG. 17 and the display panel shown in FIG. 5 lies in that the first film layer 110 defines two pixel openings in the side thereof away from the substrate 70 in an enclosing manner, the adjacent pixel openings being spaced apart from each other, and the second region L2 being located between the plurality of pixel openings. As shown in FIG. 17, the light-emitting functional layer 202 in the pixel opening extends along a surface of the second region L2 and is connected to the light-emitting functional layer 202 in the adjacent pixel opening. That is, the light-emitting functional layer 202 is prepared integrally, which simplifies the preparation process of the light-emitting functional layer and reduces the number of masks used in the preparation process. The second electrode layer 203 in the pixel opening extends along the surface of the second region L2 and is connected to the electrode layer 203 in the adjacent pixel openings. That is, the second electrode layer 203 is prepared integrally, which simplifies the preparation process of the electrode layer and reduces the number of the masks used in the preparation process.

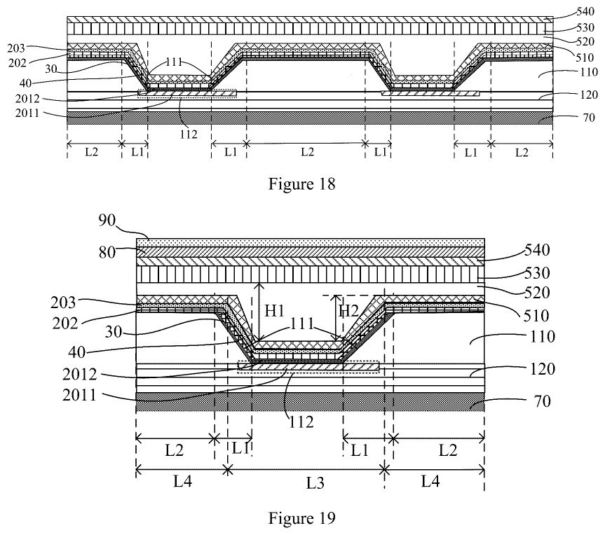

FIG. 18 is a structural schematic diagram of a display panel according to yet another embodiment of the present application. The difference between the display panel shown in FIG. 18 and the display panel shown in FIG. 17 lies in that the reflective layer 30 and the insulation layer 40 cover the pixel openings and the surface, away from the substrate 70, of the second region L2 between the adjacent pixel openings. That is, the reflective layer 30 extends along the surface of the second region L2 and is connected to the reflective layer 30 in the adjacent pixel opening. When the second sub-electrode layer 2012 and the reflective layer 30 are made of the same material, the reflective layer 30 and the second sub-electrode layer 2012 are prepared simultaneously, which simplifies the preparation process and reduces the number of the masks required. However, in this case, the reflective layer 30 is conductive, so that the insulation layer 40 needs to be provided to cover the reflective layer 30. The insulation layer 40 extends along the surface of the second region L2 and is connected to an insulation layer 40 in the adjacent pixel opening. That is, the insulation layer 40 covers the region of the first film layer 110 other than the bottom portion 112, so as to cover the entire reflective layer 30.

In the case of having two or more pixel openings, the shape of the side of the third film layer 520 away from the substrate 70 may also be the shape of the side of the third film layer 520 away from the substrate 70 shown in FIGS. 9 to 16, which will not be repeated herein.

FIG. 19 is a structural schematic diagram of a display panel according to yet another embodiment of the present application. The difference between the display panel shown in FIG. 19 and the display panel shown in FIG. 5 lies in that the display panel shown in FIG. 19 further includes a protective layer 80 and a cover plate 90. The second film layer 510, the third film layer 520, the fourth film layer 530 and the fifth film layer 540 constitute an encapsulation layer of the display panel. The protective layer 80 may be an optical clear adhesive (OCA). The cover plate 90 may be a glass cover plate.

The upstream products of the display panel provided in the embodiments of the present application may be high-refractive index materials and low-refractive index materials, and the downstream products may be mobile phones.

In a second aspect, an embodiment of the present application provides a method for preparing a display panel. The preparation method is used for preparing the display panel in the above embodiments.

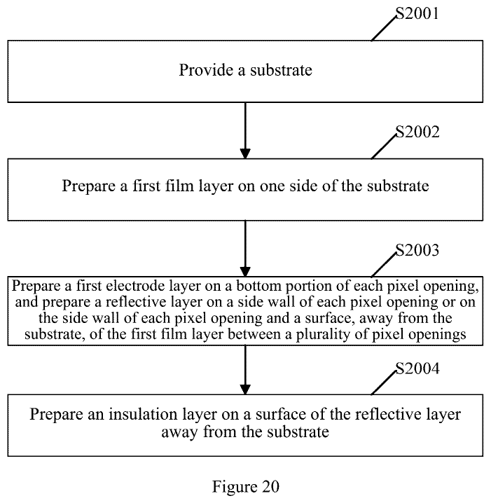

FIG. 20 is a flowchart of a method for preparing a display panel according to an embodiment of the present application. As shown in FIG. 20, the method includes the following steps.

At step S2001, a substrate is provided.

In the embodiments of the present application, the substrate is a glass substrate or a flexible substrate.

At step S2002, a first film layer is prepared on one side of the substrate. The first film layer defines at least two pixel openings spaced apart from each other in an enclosing manner.

In the embodiments of the present application, the first film layer is a pixel defining layer, a material of the first film layer is formed on one side of the substrate, and at least two pixel openings spaced apart from each other are formed by a patterning process. In one embodiment, before preparation of the first film layer, an array film layer is prepared on one side of the substrate, and the array film layer includes a plurality of film layers.

In one embodiment, the first film layer and a sixth film layer are prepared on the same side of the substrate. The sixth film layer is part of the array film layer. The first film layer is a pixel defining layer, the sixth film layer is a planarization layer, and the first film layer and the sixth film layer are both made of organic materials and are made of the same organic material. An organic material layer is formed on one side of the substrate, and holes are formed in the organic material layer to form at least two pixel openings spaced apart from each other. In one embodiment, the pixel openings may be formed by means of laser etching, photoetching, chemical dry etching, halftone process, etc. For example, the organic material layer is exposed for hole formation by means of a halftone process to form the pixel openings. The first film layer and the sixth film layer are formed in one procedure, which simplifies the preparation process and reduces the number of the masks required. In the embodiments of the present application, each pixel opening includes a bottom portion and a side wall arranged on a peripheral side of the bottom portion. In one embodiment, the side wall is obliquely arranged on the peripheral side of the bottom portion.

At step S2003, a first electrode layer is prepared at the bottom portion of each pixel opening, and a reflective layer is prepared on the side wall of each pixel opening or prepared on the side wall of each pixel opening and a surface, away from the substrate, of the first film layer between the plurality of pixel openings.

In the embodiments of the present application, the first electrode layer includes a first sub-electrode layer and a second sub-electrode layer. The first sub-electrode layer is electrically connected to a metal layer in the sixth film layer. During preparation of the first sub-electrode layer, holes are formed in the sixth film layer above the metal layer of the sixth film layer, a conductive layer is then prepared on a side of the sixth film layer 120 away from the substrate 70, the conductive layer can fill the holes, and the conductive layer is patterned to obtain the first sub-electrode layer.

In the embodiments of the present application, the second sub-electrode layer may be prepared synchronously with the reflective layer. That is, the conductive material is prepared at the bottom portion and the side wall of each pixel opening, or prepared at the bottom portion and the side wall of each pixel opening and the surface, away from the substrate, of the first film layer between the plurality of pixel openings. The conductive material layer at the bottom portions of the pixel openings is the second sub-electrode layer; and the conductive material layer located on the side wall of each pixel opening and on the surface, away from the substrate, of the first film layer between the plurality of pixel openings is the reflective layer.

At step S2004, an insulation layer is prepared on a surface of the reflective layer away from the substrate.

In the embodiments of the present application, the insulation layer covers at least the reflective layer, and the insulation layer should not cover the first electrode layer.

The specific working principle and benefits of the preparation method provided in the embodiments of the present application are similar to the specific working principle and benefits of the display panel provided in the embodiments of the present application, which will not be repeated herein.

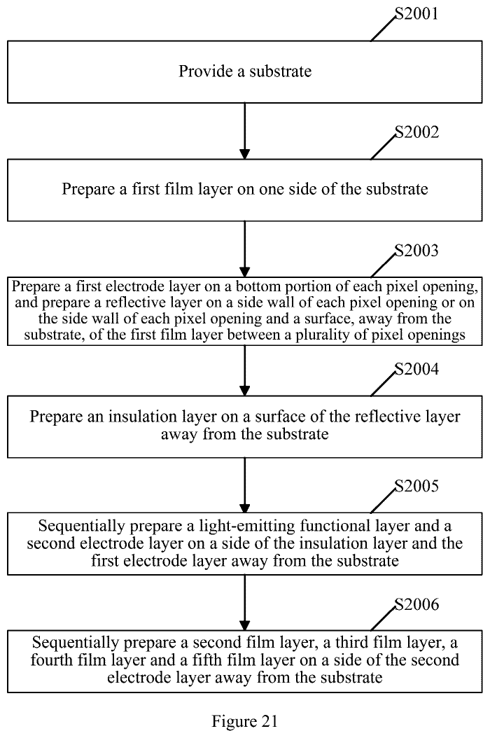

FIG. 21 is a flowchart of a method for preparing a display panel according to yet another embodiment of the present application. The difference between the method shown in FIG. 21 and the method shown in FIG. 20 lies in that the method further includes the following steps.

At step S2005, a light-emitting functional layer and a second electrode layer are sequentially prepared on a side of the insulation layer and the first electrode layer away from the substrate.

In the embodiments of the present application, the light-emitting functional layer and the second electrode layer may be prepared integrally, which simplifies the preparation process and reduces the number of the masks used in the preparation process. Since the insulation layer is arranged between the reflective layer and the light-emitting functional layer, only the light-emitting functional layer at the bottom portion of the pixel opening can emit light, thereby avoiding the crosstalk of light.

At step S2006, a second film layer, a third film layer, a fourth film layer and a fifth film layer are sequentially prepared on a side of the second electrode layer away from the substrate. The refractive index of the third film layer is greater than or equal to the refractive index of the second film layer. The refractive index of the fourth film layer is less than the refractive index of the third film layer.

In the embodiments of the present application, the second film layer and the fifth film layer are both made of inorganic materials, and may be prepared by means of a CVD process. The third film layer and the fourth film layer are both made of organic materials, and may be prepared by means of an IJP process. The second film layer, the third film layer, the fourth film layer and the fifth film layer may also be prepared by means of other conventional processes.

In one embodiment, the third film layer may be patterned. For example, the third film layer is patterned to form the shape of the third film layer as shown in FIGS. 9 to 16. The present application does not limit the patterning method, as long as the patterned third film layer can be obtained.

The specific working principle and benefits of the preparation method provided in the embodiments of the present application are similar to the specific working principle and benefits of the display panel provided in the embodiments of the present application, which will not be repeated herein.

In a third aspect, an embodiment of the present application further provides a display device. The display device includes a display panel in the above embodiments.

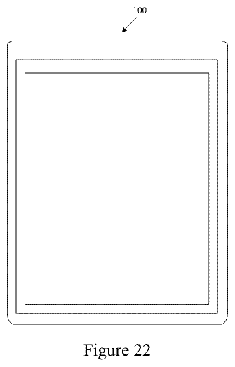

FIG. 22 is a structural schematic diagram of a display device according to an embodiment of the present application. As shown in FIG. 22, the display device 100 is a product having an image display function. For example, the display device 100 may be used to display static images, such as pictures or photos. The display device 100 may also be used to display dynamic images, such as videos.

The display device 100 may be a laptop computer, a mobile phone, a handheld or portable computer, a camera, a video camera, a vehicle-mounted intelligent central control screen, a calculator, a smart watch, a GPS navigator, an electronic photograph, electronic billboard or signboard, a projector, etc.

The display device 100 includes a display panel according to any one of the above embodiments. The display panel may be an organic light-emitting diode display panel or a quantum dot electroluminescent display panel.

In addition, the display device 100 may also have functions such as photographing, video recording, fingerprint recognition and face recognition. Accordingly, the display device 100 further includes at least one functional module for implementing the above functions, such as an under-display camera, or an under-display fingerprint recognition sensor.

The foregoing description has been presented for the purposes of illustration and description. Furthermore, this description is not intended to limit the embodiments of the present application to the forms disclosed herein. Although various exemplary aspects and embodiments have been discussed above, it is recognized that some variations, modifications, alterations, additions and sub-combinations thereof.

What is claimed is:

1. A display panel, comprising:
a substrate;
a first film layer arranged on one side of the substrate and defining at least one pixel opening in an enclosing manner, a pixel opening comprising a bottom portion and a side wall arranged on a peripheral side of the bottom portion;
a first electrode layer located at the bottom portion of the pixel opening;
a reflective layer located on a side of the first film layer away from the substrate and covering at least the side wall;
a light-emitting functional layer located on a side of the first electrode layer away from the substrate; and
a second electrode layer located on a side of the light-emitting functional layer away from the substrate.

2. The display panel according to claim 1, wherein the first electrode layer comprises a first sub-electrode layer and a second sub-electrode layer located on a side of the first sub-electrode layer away from the substrate; and the first sub-electrode layer comprises a reflective material, or the second sub-electrode layer comprises a reflective material.

3. The display panel according to claim 2, wherein the first sub-electrode layer is made of a material comprising indium tin oxide, and the second sub-electrode layer comprises a stacked structure of indium tin oxide/silver/indium tin oxide; and
a thickness of the first sub-electrode layer in a direction perpendicular to the substrate is greater than or equal to 300 nm and less than or equal to 400 nm; or a thickness of the second sub-electrode layer in the direction perpendicular to the substrate is greater than or equal to 120 nm and less than or equal to 130 nm.

4. The display panel according to claim 2, further comprising:
an insulation layer located between the reflective layer and the light-emitting functional layer and covering at least the reflective layer;
wherein the reflective layer comprises a conductive material; and the conductive material comprises at least one of silver, gold and platinum.

5. The display panel according to claim 4, wherein the reflective layer comprises a stacked structure of indium tin oxide/silver/indium tin oxide.

6. The display panel according to claim 4, wherein the insulation layer is made of a material comprising an inorganic insulation material; and
a thickness of the insulation layer in the direction perpendicular to the substrate is greater than or equal to 150 nm and less than or equal to 200 nm.

7. The display panel according to claim 4, further comprising a second film layer, a third film layer and a fourth film layer which are sequentially stacked on a side of the second electrode layer away from the substrate, wherein a refractive index of the fourth film layer is less than a refractive index of the third film layer, and the refractive index of the third film layer is greater than or equal to a refractive index of the second film layer; and
the third film layer fills at least entire part of the pixel opening.

8. The display panel according to claim 7, wherein the first film layer comprises a first region located between the side wall and the substrate and a second region surrounding the pixel opening, an orthographic projection of the first region on the substrate overlapping with an orthographic projection of the side wall on the substrate; and
the light-emitting functional layer covers the second sub-electrode layer and the first region and the second region of the first film layer;
or the second electrode layer covers the second sub-electrode layer and the first region and the second region of the first film layer.

9. The display panel according to claim 8, wherein the second film layer comprises a first section and a second section connected to the first section, the first section covering the side wall and the bottom portion, the second section being located on a surface of a side of the second region away from the substrate, and at least part of the second section contacted with the fourth film layer; and
a maximum thickness of the third film layer in the direction perpendicular to the substrate is greater than or equal to a maximum distance between the first section and the second section.

10. The display panel according to claim 7, wherein the maximum thickness of the third film layer in the direction perpendicular to the substrate is greater than or equal to 2 μm and less than or equal to 3 μm.

11. The display panel according to claim 7, wherein a side of the third film layer away from the substrate covers at least the pixel opening; and
a surface of the third film layer away from the substrate comprises a first portion and a second portion, an orthographic projection of the first portion on the substrate covering at least the pixel opening, and the second portion surrounding the first portion and being connected to the first portion.

12. The display panel according to claim 11, wherein a shape of a cross section of the second portion in the direction perpendicular to the substrate is any one of: an arc, a straight segment perpendicular to the substrate, and a straight segment at a preset angle to the substrate;
or a shape of the cross section of the first portion in the direction perpendicular to the substrate is an arc or is a straight segment parallel to the substrate.

13. The display panel according to claim 8, wherein the reflective layer covers the side wall and at least part of a surface, away from the substrate, of the second region of the first film layer;
or the insulation layer covers the side wall and at least part of the surface, away from the substrate, of the second region of the first film layer.

14. The display panel according to claim 7, further comprising a fifth film layer arranged on a side of the fourth film layer away from the substrate, wherein
the first film layer is made of an organic material;
the third film layer or the fourth film layer is made of an organic material; and
the second film layer or the fifth film layer is made of an inorganic material.

15. The display panel according to claim 1, further comprising: a sixth film layer arranged on a side of the first film layer close to the substrate, wherein
the first film layer or the sixth film layer is made of an organic material;
a maximum thickness of the first film layer in the direction perpendicular to the substrate is greater than or equal to 1 μm and less than or equal to 2 μm; and
the sum of the maximum thickness of the first film layer and a maximum thickness of the sixth film layer in the direction perpendicular to the substrate is greater than or equal to 4 μm and less than or equal to 5 μm.

16. The display panel according to claim 1, wherein the side wall is obliquely arranged on the peripheral side of the bottom portion; and
the side wall is a straight line or an arc with respect to a cross section along the direction perpendicular to the substrate.

17. The display panel according to claim 16, wherein an angle between the side wall and the bottom portion is an obtuse angle; and
the side wall is a straight line with respect to the cross section along the direction perpendicular to the substrate, and the obtuse angle is greater than or equal to 135° and less than or equal to 145°.

18. The display panel according to claim 8, wherein the first film layer defines at least two pixel openings in a side away from the substrate in an enclosing manner, the adjacent pixel openings are spaced apart from each other, and the second region is located between the plurality of the pixel openings.

19. The display panel according to claim 18, wherein the reflective layer extends along a surface of the second region and is connected to the reflective layer in the adjacent pixel opening;
the insulation layer extends along the surface of the second region and is connected to the insulation layer in the adjacent pixel opening; and
the light-emitting functional layer in the pixel opening extends along the surface of the second region and is connected to the light-emitting functional layer in the adjacent pixel opening, or the second electrode layer in the pixel opening extends along the surface of the second region and is connected to the second electrode layer in the adjacent pixel opening.

20. A display device, comprising:
a display panel further comprising,
a substrate;
a first film layer arranged on one side of the substrate and defining at least one pixel opening in an enclosing manner, the pixel opening comprising a bottom portion and a side wall arranged on a peripheral side of the bottom portion;
a first electrode layer located at the bottom portion of the pixel opening;
a reflective layer located on a side of the first film layer away from the substrate and covering at least the side wall;
a light-emitting functional layer located on a side of the first electrode layer away from the substrate; and
a second electrode layer located on a side of the light-emitting functional layer away from the substrate.
